(19) United States
(12) Patent Application Publication
(10) Pub. No.: US 2022/0262865 A1
(43) Pub. Date: Aug. 18, 2022

(54) DISPLAY PANEL, DISPLAY DEVICE AND MANUFACTURING METHOD THEREOF

(71) Applicants: BOE TECHNOLOGY GROUP CO., LTD., Beijing (CN); Chengdu BOE Optoelectronics Technology Co., Ltd., Chengdu, Sichuan, (CN)

(72) Inventors: Peng HOU, Beijing (CN); Yunhao WANG, Beijing (CN); Yongzhan HAN, Beijing (CN); Huaisen REN, Beijing (CN); Yuan HE, Beijing (CN)

(21) Appl. No.: 17/630,641

(22) PCT Filed: Apr. 9, 2021
(86) PCT No.: PCT/CN2021/086096

§ 371 Date: Jan. 27, 2022

(30) Foreign Application Priority Data
May 25, 2020 (CN) 202010449067.9

(51) Int. Cl. H01L 27/32; H01L 51/56; G06F 3/044

(52) U.S. Cl. CPC H01L 27/322; H01L 27/323; H01L 51/56; H01L 51/5284; H01L 27/3246; H01L 2227/323; G06F 3/0446

(57) ABSTRACT

Provided are a display panel, a display device and a manufacturing method thereof. The display panel includes a display substrate and a color film functional layer located on a light exit side of the display substrate. The display substrate includes a base substrate, a pixel circuit disposed on the base substrate, a light-emitting element layer, and a planarization layer. The light-emitting element layer includes a pixel defining layer, and pixel openings for defining pixel units are formed in the pixel defining layer. The color film functional layer includes a planarization transparent base layer disposed on a surface away from the display substrate, and a plurality of accommodating grooves in different depths are formed in the planarization transparent base layer. Color filter blocks are arranged in the accommodating grooves, and orthographic projections of the color filter blocks on the display substrate cover the pixel openings of the display substrate.

### CROSS-REFERENCE TO RELATED APPLICATIONS

The present disclosure claims the priority to the Chinese Patent Application No. 202010449067.9, filed on May 25, 2020, entitled “DISPLAY PANEL, DISPLAY DEVICE AND MANUFACTURING METHOD THEREOF”.

### TECHNICAL FIELD

The present disclosure relates to the field of display technologies, and in particular, to a display panel, a display device, and a manufacturing method of the display device.

### BACKGROUND

With the development of display technologies, display devices having a touch function (i.e., touch display devices) have been produced. Among the touch display devices currently on the market, there is a touch display device with a touch functional layer located at the outermost side thereof. However, such touch display device generally has the disadvantages such as narrow viewing angle and poor display effect.

### SUMMARY

The present disclosure aims to provide a display panel, a display device, and a method for manufacturing the display device.

As a first aspect of the present disclosure, a display panel is provided. The display panel includes a display substrate and a color film functional layer located on a light exit side of the display substrate. The color film functional layer includes a planarized transparent base layer and a color film layer, the planarized transparent base layer is on the display substrate, and a plurality of accommodating grooves are on a surface of the planarized transparent base layer away from the display substrate. The color film layer includes a plurality of color filter blocks in various colors, the plurality of color filter blocks are arranged in the plurality of accommodating grooves, orthographic projections of the plurality of accommodating grooves on the display substrate overlap with orthographic projections of the plurality of color filter blocks on the display substrate, and the orthographic projections of the plurality of color filter blocks on the display substrate cover pixel openings of the display substrate.

Optionally, the plurality of accommodating grooves for accommodating the plurality of color filter blocks in various colors have at least two different depths.

Optionally, the plurality of color filter blocks includes a red filter block, a green filter block, and a blue filter block; and among the accommodating groove for accommodating the green filter block, the accommodating groove for accommodating the red filter block, and the accommodating groove for accommodating the blue filter block, the accommodating groove for accommodating the green filter block has a largest depth.

Optionally, a surface of the color film functional layer away from the display substrate is a plane/flat surface. Optionally, the planarized transparent base layer includes a positive photoresist, and the plurality of color filter blocks includes a negative photoresist.

Optionally, the display substrate includes a base substrate, a pixel circuit on the base substrate, a light-emitting element layer, and a planarization layer, the light-emitting element layer includes a plurality of light-emitting elements, and the plurality of light-emitting elements corresponds to one of the pixel units. The light-emitting element layer is between the color film functional layer and the base substrate, the planarization layer is between the pixel circuit and the light-emitting element layer, and an orthographic projection of the planarization layer on the base substrate covers the pixel circuit.

The pixel circuit is electrically connected to anodes of the light-emitting elements through vias penetrating the planarization layer, and a thin film transistor of the pixel circuit is an oxide thin film transistor.

Light transmittance of the planarization layer relative to light having wavelengths from 300 nm to 460 nm does not excess a predetermined percentage, and the predetermined percentage is in a range from 5% to 10%. A material of the planarization layer is a green filter material includes a negative photoresist, or a red filter material includes a negative photoresist.

As a second aspect, a display device is provided. The display device includes a display panel described above. The display device further includes a touch functional layer on a side of the color film functional layer away from the display panel.

Optionally the touch functional layer includes a bridge electrode layer, a touch electrode layer, and an insulating spacer layer between the bridge electrode layer and the touch electrode layer. The bridge electrode layer includes a plurality of first bridge electrodes. The touch electrode layer includes a plurality of touch electrodes and a plurality of second bridge electrodes. The plurality of touch electrodes are arranged in rows and columns. The first bridge electrodes are configured to connect the touch electrodes in a row direction, and the second bridge electrodes are configured to connect the touch electrodes in a column direction. The bridge electrode layer is on a surface of the color film functional layer away from the display panel.

Optionally, the plurality of first bridge electrodes, the plurality of second bridge electrodes and the plurality of touch electrodes of the touch functional layer includes a metal material. The plurality of touch electrode are formed into a grid shape with a plurality of grid openings, and the plurality of color filter blocks correspond to the plurality of grid openings.

Optionally, the touch functional layer further includes a black matrix at least covering the touch electrode layer, light outlets are formed in the black matrix, and the light outlets of the black matrix correspond to the plurality of grid openings.

Optionally, an area of a surface of the black matrix away from the color film functional layer is smaller than an area of a surface of the black matrix proximal to the color film functional layer, so as to form side surfaces of the light outlets as an inclined surface.

Optionally, the touch functional layer further includes a transparent protective layer, and an orthographic projection of the transparent protective layer on the base substrate covers a layer where the black matrix are located.

Optionally, the transparent protective layer includes a transparent substrate and a plurality of scattering particles dispersed in the transparent substrate.

Optionally, the transparent protective layer includes scattering blocks and a transparent protective layer, with the scattering blocks being located in the plurality of light outlets, and the transparent protective layer being on a side of the scattering blocks away from the display panel, and each of the scattering blocks includes a transparent substrate and a plurality of scattering particles dispersed in the transparent substrate.

Optionally, the plurality of scattering particles have the same colors as the colors of the plurality of color filter blocks.

Optionally, a thickness of the transparent protective layer is 1 to 3 times a thickness of the black matrix.

As a third aspect of the present disclosure, a method for manufacturing a display device is provided. The method includes: providing a display substrate; providing a color film functional layer, comprising: forming a planarized transparent base layer, with a plurality of accommodating grooves formed on a surface of the planarized transparent base layer away from a display panel; and forming a color film layer comprising a plurality of color filter blocks in various colors, with the plurality of color filter blocks located in the plurality of accommodating grooves, orthographic projections of the plurality of accommodating grooves on the display substrate overlapping with orthographic projections of the plurality of color filter blocks on the display substrate, and the orthographic projections of the plurality of color filter blocks on the display substrate covering pixel openings of the display substrate; and providing a touch functional layer.

Optionally, providing the touch functional layer includes: forming a bridge electrode layer including a plurality of first bridge electrodes; forming an insulating spacer layer; forming a touch electrode layer including a plurality of touch electrodes and a plurality of second bridging electrodes, with the plurality of touch electrodes arranged in rows and columns, the plurality of first bridge electrodes configured to connect the touch electrodes in a row direction, the plurality of second bridge electrodes configured to connect the touch electrodes in a column direction, the plurality of touch electrodes includes a metal material, the plurality of touch electrodes formed into a grid shape with a plurality of grid openings, and the plurality of color filter blocks corresponding to the plurality of grid openings; forming a black matrix layer, with light outlets formed in black matrix covering the plurality of touch electrodes, and the light outlets of the black matrix corresponding to the plurality of grid openings; and forming a transparent protective layer.

Optionally, forming the transparent protective layer includes: forming scattering blocks in the light outlets of the black matrix, with each of the scattering blocks including a transparent substrate and scattering particles dispersed in the transparent substrate, and colors of the scattering particles being the same as colors of the plurality of color filter blocks; and forming an outer transparent protective layer; or forming the transparent protective layer includes: the transparent protective layer includes a transparent substrate and scattering particles dispersed in the transparent substrate, and colors of the scattering particles are the same as colors of the plurality of color filter blocks.

### BRIEF DESCRIPTION OF DRAWINGS

The accompanying drawings are intended to provide a further understanding of the present disclosure, and are incorporated in and constitute a part of the specification. The drawings are used to explain the present disclosure in conjunction of the specific embodiments below, but do not constitute any limitation to the present disclosure. In the drawings:

FIG. 1 is a schematic diagram of a display panel according to an embodiment the present disclosure;

FIG. 2 is a schematic diagram of a display device according to an embodiment the present disclosure;

FIG. 3 is a schematic diagram of a display device according to another embodiment the present disclosure;

FIG. 4 is a schematic diagram of a display device according to still another embodiment the present disclosure;

FIG. 5 is a schematic diagram of a via obtained by exposure of a positive photoresist;

FIG. 6 is a schematic diagram of a via obtained by exposure of a negative photoresist;

FIG. 7 is a scanned picture of a via made from a negative photoresist;

FIG. 8 is a schematic diagram of a light outlet with a sidewall that is an inclined surface;

FIG. 9 is a schematic diagram of a light outlet with a sidewall that is a vertical surface;

FIG. 10 is a flowchart illustrating a manufacturing method according to the present disclosure;

FIG. 11 is a schematic diagram of step S221 according to an embodiment;

FIG. 12 is a schematic diagram of step S230 according to an embodiment;

FIG. 13 is a schematic diagram of step S235 according to an embodiment;

FIG. 14 is a top view of a touch electrode layer and a bridge electrode layer;

FIG. 15 is a schematic diagram showing light exiting from a color filter block after a planarization layer is disposed on an outer side of the color filter block; and

FIG. 16 is a schematic diagram showing light exiting from a color filter block in a display panel according to the present disclosure.

### DETAIL DESCRIPTION OF EMBODIMENTS

Specific embodiments of the present disclosure are described in detail below with reference to the accompanying drawings. It should be understood that the specific embodiments described below are merely used to illustrate and explain the present disclosure, rather than limiting the present disclosure.

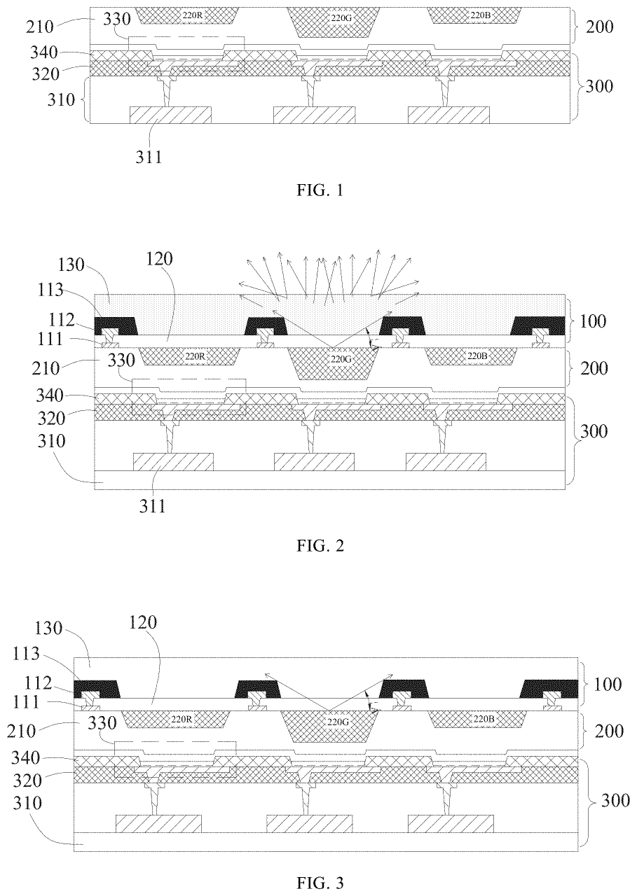

In one aspect of the present disclosure, a display panel is provided. As shown in FIG. 1, the display panel includes a display substrate 300 and a color film functional layer 200 located on a light exit side of the display substrate 300. The color film functional layer 200 includes a planarized transparent base layer 210 and a color film layer. The planarized transparent base layer 210 is disposed on the display substrate 300, and a plurality of accommodating grooves are formed on a surface of the planarized transparent base layer 210 away from the display substrate 300. The color film layer includes a plurality of color filter blocks in various colors, the color filter blocks are arranged in the accommodating grooves, orthographic projections of the accommodating grooves on the display substrate 300 overlap with those of the color filter blocks on the display substrate 300, and the orthographic projections of the color filter blocks on the display substrate 300 cover pixel openings of the display substrate 300.

It should be noted that a depth direction of the accommodating groove is consistent with a thickness direction of the display substrate, and the “thickness direction” here refers to a direction perpendicular to a light exit surface of the display substrate 300.

In the present disclosure, at least a part of the color filter block is disposed in the accommodating groove, so that the part of the color filter block protruding from the planarized transparent base layer 210 is smaller or the color filter block does not protrude from the planarized transparent base layer 210. When the display panel performs display, light emitted from each pixel opening of the display substrate 100 passes through the corresponding color filter blocks, and then exits from surfaces of the color filter blocks.

A display device can be obtained by preparing a touch functional layer 100 on the display panel provided by the present disclosure. As shown in FIG. 2, the touch functional layer 100 is disposed on a side of the color film functional layer 200 away from the display substrate 300. Since at least a part of each color filter block is located in the corresponding accommodating groove, a height difference between a light exit surface of the color filter block and the planarized transparent base layer 210 is relatively small or even equal to 0.

In the related art, the color filter block is directly arranged on the planarized transparent base layer, so that the height difference between the color filter block and the planarized transparent base layer is relatively large, a planarization layer with a relatively large thickness needs to be additionally arranged on an outer side of the color filter blocks, and then the touch functional layer is formed on the planarization layer. Opaque components such as signal lines in the touch functional layer may block light. Since the light is emitted in a divergent manner, under the condition that a distance between two adjacent blocking objects is the same, the farther the blocking objects are from a light source, the more the emitted light is blocked.

As shown in FIG. 15, a planarization layer P is additionally disposed on the surfaces of the color filter blocks. In FIG. 16, no planarization layer is disposed on the surfaces of the color filter blocks. It is obvious that the embodiment shown in FIG. 16 achieves larger light output and wider viewing angle.

As an embodiment of the present disclosure, a surface of the color film functional layer 200 away from the display substrate 100 may be a plane, so that the touch functional layer 100 may be directly formed on the color film functional layer 200, without additionally forming a planarization layer on the color film functional layer 200, thereby decreasing an overall thickness of the touch display device, and facilitating lightening and thinning of the touch display device. Moreover, light emitted by a pixel unit of the display substrate 300 may exit from the touch display device only after passing through the color film functional layer 200 and the touch functional layer 100, so that light extraction efficiency of the touch display device is further improved, brightness of the display device is improved, and energy consumption of the touch display device is reduced.

The filter blocks in various colors are different in light transmittance. Optionally, a thickness of the color filter block with low light transmittance is less than that of the color filter block with high light transmittance, so as to realize a better color display effect. For example, for a color film functional layer having a red filter block 220R, a green filter block 220G and a blue filter block 220B, the light transmittance of the blue filter block 220B is the lowest, the light transmittance of the green filter block 220G is the highest, and the light transmittance of the red filter block 220R is between the light transmittance of the blue filter block 220B and the light transmittance of the green filter block 220G. Therefore, the thickness of the green filter block 220G is the largest, and the thickness of the blue filter block 220B is the smallest. The thickness of the red filter block 220R may be between the thickness of the green filter block 220G and the thickness of the blue filter block 220B.

Specifically, when the color film functional layer 200 of the display panel is prepared, a planarized initial material layer is first formed, the accommodating grooves with different depths are formed in the planarized initial material layer, and then the color filter blocks are formed in the corresponding accommodating grooves, so as to finally obtain the color filter blocks with different thicknesses.

It should be noted that the color filter blocks in the same color have the same thickness, and the accommodating grooves for accommodating the color filter blocks in the same color have the same depth.

For example, in the embodiment shown in FIG. 1, the color filter blocks of the color film functional layer 200 include a plurality of red filter blocks 220R, a plurality of green filter blocks 220G with the largest thickness, and a plurality of blue filter blocks 220B. Accordingly, among the accommodating grooves for accommodating the green filter blocks 200G, the accommodating grooves for accommodating the red filter blocks 200R, and the accommodating grooves for accommodating the blue filter blocks 200B, the depth of the accommodating grooves for accommodating the green filter blocks 200G is the largest.

In order to improve flatness of the surface of the color film functional layer 200 away from the display substrate 300, optionally, the planarized transparent base layer 210 is made of a positive photoresist, and the plurality of color filter blocks are made of a negative photoresist.

After the planarized transparent base layer 210 having the plurality of accommodating grooves is made of the positive photoresist, and the plurality of color filter blocks with flat surfaces may be made from the negative photoresist, so that the overall flatness of the color film functional layer 200 can be improved.

In the present disclosure, a specific structure of the display substrate 300 is not particularly limited, for example, the display panel may be a liquid crystal display panel or an organic light-emitting diode display panel.

In the specific embodiments shown in FIG. 1 to FIG. 4, the display substrate 300 is an organic light-emitting diode display panel. Specifically, the display substrate 300 includes a base substrate 310, a pixel circuit disposed on the base substrate 310, a light-emitting element layer, and a planarization layer 320. The light-emitting element layer is located between the color film functional layer 200 and the base substrate 310, the planarization layer 320 is located between the pixel circuit and the light-emitting element layer, and an orthographic projection of the planarization layer 320 on the base substrate 310 covers the pixel circuit. The light-emitting element layer includes a plurality of light-emitting elements 330, and the pixel circuit is electrically connected to anodes of the light-emitting elements 330 through vias penetrating the planarization layer 320. Further, the light-emitting element layer may include light-emitting elements 330 that emit light in various colors. For example, the light-emitting element layer may include a light-emitting element that emits red light, a light-emitting element that emits blue light, and a light-emitting element that emits green light.

Optionally, the light-emitting element layer may further include a pixel defining layer 340 in which pixel openings for defining pixel units are formed.

Optionally, in order to improve a response speed, a thin film transistor 311 of the pixel circuit is an oxide thin film transistor, the planarization layer 320 is capable of absorbing ultraviolet light, and light transmittance of the planarization layer 320 for light having wavelengths from 300 nm to 460 nm does not excess a predetermined percentage.

During a photolithography process for manufacturing a display panel, g-LINE light (having a wavelength of 460 nm) or i-LINE light (having a wavelength of 365 nm, that is, the ultraviolet light) is introduced according to a photosensitive material. An active layer of the oxide thin film transistor is made of an oxide which is a photosensitive material. The planarization layer 320 is capable of absorbing the ultraviolet light introduced after the thin film transistor 311 is prepared, and may reduce adverse effects on the active layer of the oxide thin film transistor during a subsequent optical process, thereby preventing a threshold voltage of the thin film transistor from drifting (usually, negatively drifting).

In the present disclosure, the predetermined percentage is not particularly limited. Optionally, in order to absorb the ultraviolet light as much as possible, the predetermined percentage is between 5% and 10%.

In the present disclosure, a specific material of the planarization layer 320 is not particularly limited as long as the planarization layer 320 is capable of absorbing the ultraviolet light. As an alternative embodiment, the planarization layer 320 may be made of a colored material.

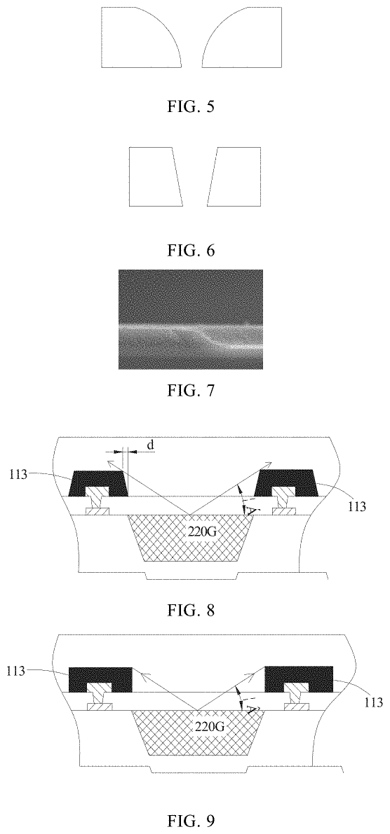

Optionally, in order to facilitate material selection, the planarization layer 320 may be made of the negative photoresist which is used to form the color filter blocks. The negative photoresist may still maintain surface flatness after exposure, so that the negative photoresist of the color filter blocks may be used to prepare the planarization layer 320 which is capable of absorbing the ultraviolet light and has good surface flatness, thereby improving product yield. The vias electrically connecting the pixel circuit to the anodes of the light-emitting elements penetrate the planarization layer 320. FIG. 5 is a schematic diagram of a via formed in a positive photoresist layer, and FIG. 6 and FIG. 7 are schematic diagrams of a via formed in a negative photoresist layer. By comparison, flatness of a sidewall of the via formed in the negative photoresist is good.

Since the material of the planarization layer 320 is the same as that of the color filter blocks, the planarization layer 320 allows light in a specific color to pass. The planarization layer and a display driving substrate under the planarization layer may be irradiated with light in the same color as the planarization layer, so as to observe and monitor structures of the TFTs, and realize Failure Analysis (FA). In the present disclosure, the specific material of the planarization layer 320 is not particularly limited, and preferably, the material of the planarization layer is a green filter material made of a negative photoresist, or a red filter material made of a negative photoresist. The red filter material and the green filter material do not have blue light transmittance, and are capable of better absorbing the light having the wavelengths from 300 nm to 460 nm.

In a second aspect of the present disclosure, a display device is provided. As shown in FIG. 2 to FIG. 4, the display device includes the display panel and the touch functional layer 100 provided in the first aspect of the present disclosure, and the touch functional layer 100 is located on the side of the color film functional layer 200 away from the display substrate 100.

In the present disclosure, a specific structure of the touch functional layer is not particularly limited. For example, the touch functional layer may be a capacitive touch panel, a resistive touch panel, or a photoelectric touch panel.

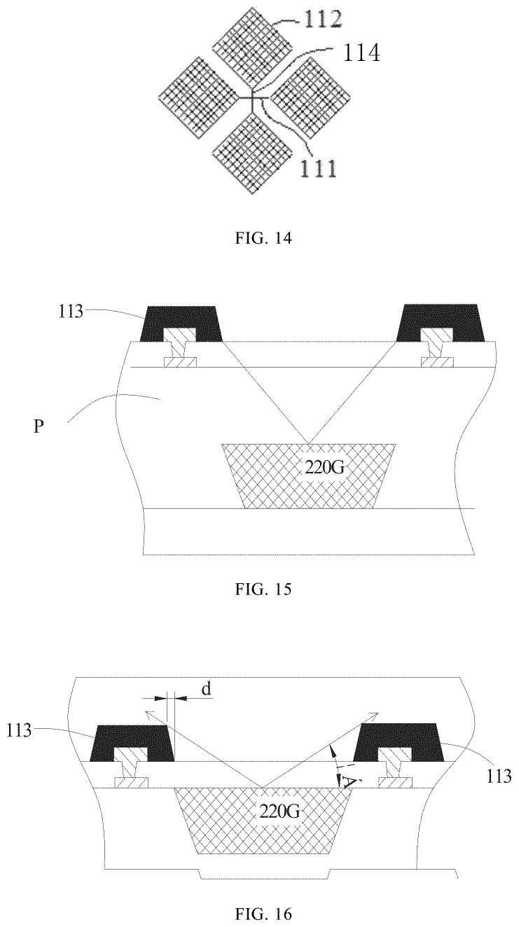

In the embodiment shown in FIG. 2, the touch functional layer 100 is a capacitive touch panel. Specifically, as shown in FIG. 2 and FIG. 14, the touch functional layer 100 includes a bridge electrode layer, a touch electrode layer, and an insulating spacer layer 120 disposed between the bridge electrode layer and the touch electrode layer. The bridge electrode layer includes a plurality of first bridge electrodes 111, and the touch electrode layer includes a plurality of touch electrodes 112 and a plurality of second bridge electrodes 113. The plurality of touch electrodes are arranged in rows and columns. The first bridge electrodes are configured to connect the touch electrodes in a row direction, and the second bridge electrodes 113 are configured to connect the touch electrodes in a column direction. The bridge electrode layer is disposed on a surface of the color film functional layer away from the display panel.

The plurality of touch control electrodes include touch driving electrodes and touch sensing electrodes. Capacitance is formed between the touch driving electrode and touch sensing electrode that are adjacent to each other. When an operator touches a light exit surface of the display device with a finger, capacitance at a touch point is changed, and position coordinates of the touch point may be determined according to the change of the capacitance.

As an alternative embodiment, the plurality of touch electrodes may include touch driving electrodes arranged in a row direction and touch sensing electrodes arranged in a column direction.

The present disclosure is not limited to the above, for example, the touch driving electrodes and the touch sensing electrodes among the touch electrodes may be located at two sides of the insulating spacer layer 120 respectively.

In the present disclosure, a specific material of the insulating spacer layer 120 is not particularly limited. As an alternative embodiment, the insulating spacer layer 120 may be made of an inorganic insulating material. For example, the insulating spacer layer 120 may be made of silicon oxide, and/or silicon nitride.

When the display substrate 300 is an organic light-emitting diode display panel, the color film functional layer 200 and the insulating spacer layer 120 made of an inorganic material may be used as a packaging layer of the organic light-emitting diode display panel. In other words, it is unnecessary to additionally provide a packaging layer for the organic light-emitting diode display panel, which may further reduce the thickness of the touch display device.

As an alternative embodiment, a specific material of the touch electrode 112 is not particularly limited in the present disclosure. As an alternative embodiment, the touch electrode 112 may be a block electrode made of a transparent electrode material (e.g., ITO).

Optionally, in order to reduce resistance of the touch electrode, the touch electrode may be made of a metal material. Specifically, the touch electrode 112 is formed in a grid shape having a plurality of grid openings, and the color filter blocks correspond to the grid openings. Optionally, in order to enhance display contrast and improve the display effect, the touch functional layer may further include a black matrix 113. Light outlets are formed in the black matrix 113, the black matrix 113 covers metal wires of the touch electrodes, and the light outlets of the black matrix 113 correspond to the grid openings of the touch electrodes and also correspond to the color filter blocks.

As an alternative embodiment, the first bridge electrodes and the second bridge electrodes of the bridge electrode layer may be made of a metal material which is the same as that of the touch electrodes.

It should be noted that the display substrate 300 is also provided with a large number of metal wires (e.g., gate lines, data lines, etc.), and the black matrix 113 may not only cover the grid wires of the touch electrodes 112 in the touch functional layer 100, but also cover the metal wires of the display substrate 300. In other words, the touch functional layer 100 and the display substrate 300 share the black matrix 113, which simplifies the structure of the touch display panel.

As an alternative embodiment, a bottom edge of a light outlet is aligned with a top edge of the color filter block corresponding to the light outlet. Optionally, in order to increase a light-emitting angle of the pixel unit corresponding to the color filter block, an area of a surface of the black matrix 113 away from the color film functional layer 200 is smaller than that of a surface of the black matrix 113 proximal to the color film functional layer 200, so as to form a side surface of the light outlet as an inclined surface.

It should be noted that the “bottom edge of the light outlet” refers to an outline of an opening formed on the surface of the black matrix proximal to the color film functional layer (i.e., the bottom edge in FIG. 2), and the “top edge of the color filter block” refers to an outline of the surface of the color filter block away from the display substrate 300 (i.e., the top edge in FIG. 2).

A principle that the inclined side surface of the light outlet can increase the light-emitting angle of the pixel unit is illustrated with reference to FIG. 8 and FIG. 9.

FIG. 8 shows an embodiment in which the side surface of the light outlet is an inclined surface, and FIG. 9 shows an embodiment in which the side surface of the light outlet is a vertical surface. The top edge of the black matrix plays a decisive role in the maximum light-emitting angle. It is apparent that an angle α between the light having the largest light-emitting angle and a top surface of the green filter block 220G shown in FIG. 8 is smaller than an angle β between the light having the largest light-emitting angle and a top surface of the green filter block 220G shown in FIG. 9.

In the present disclosure, inclination of the side surface of the light outlet is not particularly limited as long as the light-emitting angle can be increased and it can be ensured that two adjacent pixel units corresponding to the light outlets do not generate crosstalk.

Optionally, for the same light outlet, as shown in FIG. 8, a distance d between the top edge of the black matrix and the bottom edge of the black matrix is no more than half of a width of the color filter block corresponding to the light outlet. In the present disclosure, the plurality of color filter blocks are arranged in rows and columns, and the “width” here refers to a length of the color filter block in a row direction.

Optionally, in order to protect the entire touch functional layer 100, as shown in FIG. 2 to FIG. 4, the touch functional layer 100 further includes a transparent protective layer 130 which covers a layer where the black matrix 113 is located.

In the present disclosure, a specific material and a specific structure of the transparent protective layer 130 are not particularly limited as long as the transparent protective layer can perform a protective function and does not affect light emission.

In the embodiment shown in FIG. 3, the transparent protective layer 130 is made of a transparent optical adhesive doped with no scattering particles.

Optionally, in order to increase the light-emitting angle and improve the viewing angle of the touch display device, scattering particles may be doped in the transparent optical adhesive when the transparent protective layer 130 is prepared. Optionally, in order to ensure transparency, in the transparent optical adhesive mixture doped with the scattering particles, a mass percentage of the doped scattering particles is no more than 0.5%.

As for the transparent protective layer obtained by curing the transparent optical adhesive mixture, as shown in FIG. 2, the transparent protective layer 130 includes a transparent substrate and a plurality of scattering particles dispersed in the transparent substrate.

In the embodiment shown in FIG. 2, the scattering particles are uniformly distributed in the transparent substrate. The straight lines with arrows indicate light directions, and as shown in FIG. 2, the scattering particles may scatter the light entering the scattering particles, thereby increasing the light-emitting angle and improving the viewing angle of the display device.

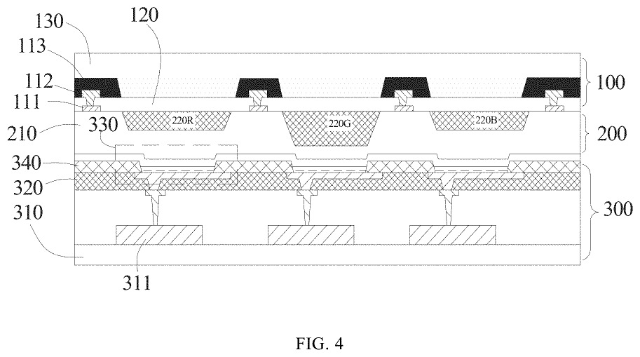

In the embodiment shown in FIG. 4, the transparent protective layer 130 includes a scattering block located in the light outlet, and a transparent protective layer disposed on a side of the scattering block away from the display panel. The scattering block includes a transparent substrate and a plurality of scattering particles dispersed in the transparent substrate.

Optionally, in order to reduce a haze of the transparent protective layer 130 and improve display contrast of the touch display device, colors of the plurality of scattering particles are the same as those of the plurality of color filter blocks.

For example, for a touch display device having three types of filter blocks, namely a red filter block, a green filter block, and a blue filter block, the scattering particles may include a red scattering particle, a green scattering particle, and a blue scattering particle.

The scattering particles have higher spectral selectivity for light having the same color as the scattering particles, and the haze of the transparent protective layer 130 can be reduced and the display contrast can be improved by providing the scattering particles in the same colors as those of the color filter blocks.

In the present disclosure, a thickness of the transparent protective layer 130 is not particularly limited. Optionally, the thickness of the transparent protective layer 130 may be 1 to 3 times the thickness of the black matrix.

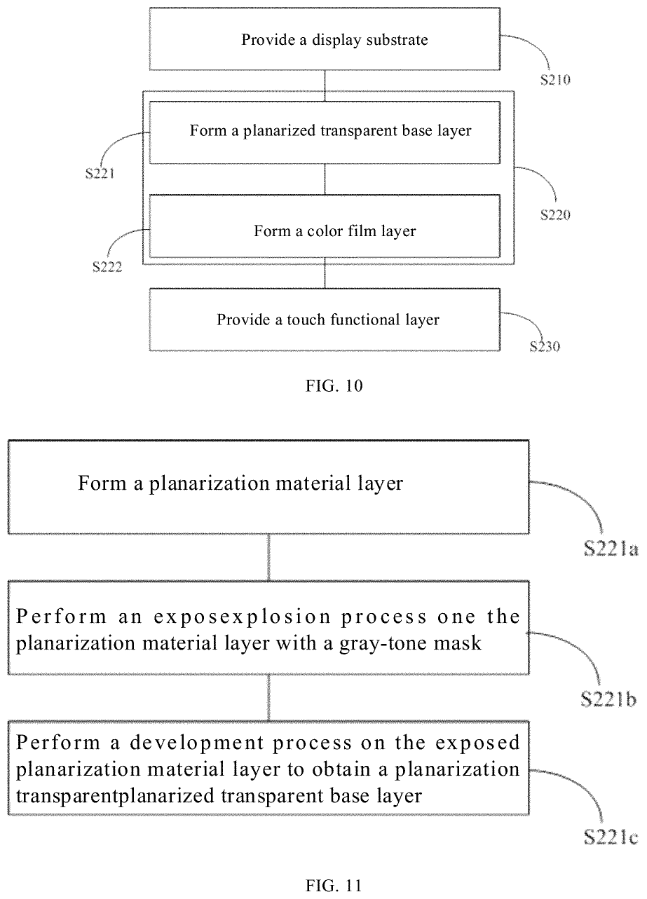

In a second aspect of the present disclosure, a method for manufacturing a display device is provided. As shown in FIG. 10, the method includes steps S210 to S230.

At step S210, a display substrate is provided.

At step S220, a color film functional layer is provided.

At step S230, a touch functional layer is provided. The step S220 includes steps S221 and S222.

At step S221, a planarized transparent base layer is formed. The planarized transparent base layer has a plurality of accommodating grooves formed on a surface thereof away from a display panel.

At step S222, a color film layer is formed. The color film layer includes a plurality of color filter blocks in various colors. The color filter blocks are located in the accommodating grooves, orthographic projections of the accommodating grooves on the display substrate overlap with those of the color filter blocks on the display substrate, and the orthographic projections of the color filter blocks on the display substrate cover pixel openings of the display substrate.

The manufacturing method provided by the present disclosure can manufacture the touch display device provided in the first aspect of the present disclosure, and the beneficial effects and the operating principle of the touch display device have been described in detail above, and thus are not repeated here.

It should be noted that, since the accommodating grooves are formed before the formation of the color filter blocks in the present disclosure, the color film functional layer with a flat surface can be easily formed.

Optionally, in order to reduce the number of masks used, as shown in FIG. 11, the step S221 may include steps S221a to S221c.

At step S221a, a planarization material layer is formed.

At step S221b, an exposure process is performed on the planarization material layer with a gray-tone mask.

At step S221c, a developing process is performed on the exposed planarization material layer to obtain a planarized transparent base layer.

The accommodating grooves with different depths can be sequentially formed with the gray tone mask during a photolithography process, which reduces the steps of the manufacturing method.

In the present disclosure, a planarization layer may be made from a positive photoresist material.

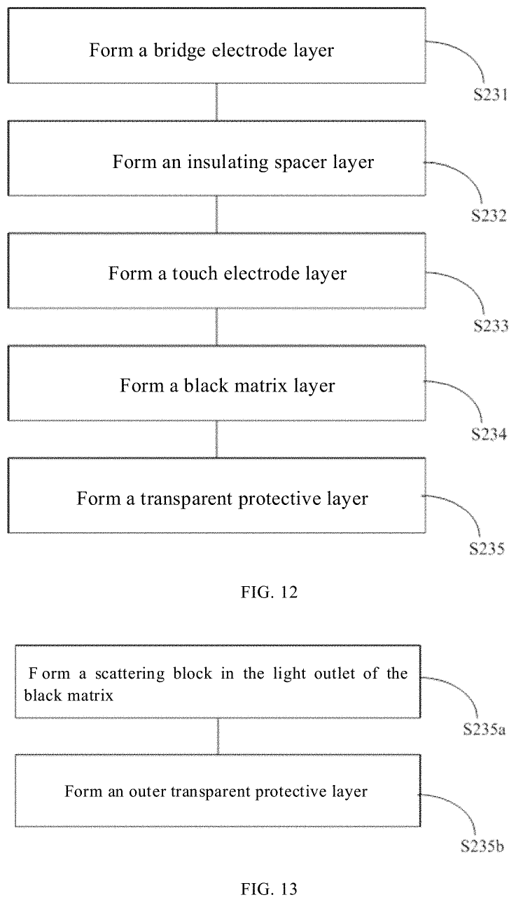

As described above, the black matrix layer is disposed in the touch functional layer, so that the display panel and the touch functional layer can share the black matrix, which can simplify the manufacturing process and reduce the overall thickness of the touch display device. Specifically, as shown in FIG. 12, the step S230 may include:

At step S231, a bridge electrode layer including a plurality of first bridge electrodes is formed.

At step S232, an insulating spacer layer is formed.

At step S233, a touch electrode layer is formed. The touch electrode layer includes a plurality of touch electrodes and a plurality of second bridge electrodes. The plurality of touch electrodes are arranged in rows and columns. The first bridge electrodes are configured to connect the touch electrodes in a row direction, and the second bridge electrodes are configured to connect the touch electrodes in a column direction. The touch electrodes are made of a metal material, the touch electrodes are formed into a grid shape with a plurality of grid openings, and the color filter blocks correspond to the grid openings.

At step S234, a black matrix layer is formed. Light outlets are formed on a black matrix which covers the touch electrodes, and the light outlets of the black matrix correspond to the grid openings.

At step S235, a transparent protective layer is formed.

In order to increase the viewing angle of the touch display device, scattering particles may be disposed in the transparent protective layer.

In order to form the transparent protective layer shown in FIG. 3, as shown in FIG. 13, the step S235 may include steps S235a and S235b.

At step S235a, a scattering block is formed in the light outlet of the black matrix. The scattering block includes a transparent substrate and scattering particles dispersed in the transparent substrate, and colors of the scattering particles are the same as those of the color filter blocks.

At step S235b, an outer transparent protective layer is formed.

In order to form the transparent protective layer shown in FIG. 2, the transparent protective layer may be made of an optical adhesive in which scattering particles are uniformly dispersed. Correspondingly, the transparent protective layer includes a transparent substrate and scattering particles dispersed in the transparent substrate, and colors of the scattering particles are the same as those of the color filter blocks.

It should be understood that the above embodiments are merely exemplary embodiments adopted to illustrate the principle of the present disclosure, and the present disclosure is not limited thereto. Various modifications and improvements can be made by those of ordinary sill in the art without departing from the spirit and essence of the present disclosure, and those modifications and improvements are also considered to fall within the scope of the present disclosure.

1. A display panel, comprising a display substrate and a color film functional layer located on a light exit side of the display substrate, wherein the color film functional layer comprises a planarized transparent base layer and a color film layer, the planarized transparent base layer is on the display substrate, and a plurality of accommodating grooves are on a surface of the planarized transparent base layer away from the display substrate; the color film layer comprises a plurality of color filter blocks in various colors, the plurality of color filter blocks are arranged in the plurality of accommodating grooves, orthographic projections of the plurality of accommodating grooves on the display substrate overlap with orthographic projections of the plurality of color filter blocks on the display substrate, and the orthographic projections of the plurality of color filter blocks on the display substrate cover pixel openings of the display substrate.

2. The display panel of claim 1, wherein the plurality of accommodating grooves for accommodating the plurality of color filter blocks in various colors have at least two different depths.

3. The display panel of claim 2, wherein the plurality of color filter blocks comprise a red filter block, a green filter block, and a blue filter block; and among the accommodating groove for accommodating the green filter block, the accommodating groove for accommodating the red filter block, and the accommodating groove for accommodating the blue filter block, the accommodating groove for accommodating the green filter block has a largest depth.

4. The display panel of claim 1, wherein a surface of the color film functional layer away from the display substrate is a plane.

5. The display panel of claim 1, wherein the planarized transparent base layer comprises a positive photoresist, and the plurality of color filter blocks comprises a negative photoresist.

6. The display panel of claim 1, wherein the display substrate comprises a base substrate, a pixel circuit on the base substrate, a light-emitting element layer, and a planarization layer, the light-emitting element layer comprises a plurality of light-emitting elements, and the plurality of light-emitting elements corresponds to the pixel openings;
the light-emitting element layer is between the color film functional layer and the base substrate, the planarization layer is between the pixel circuit and the light-emitting element layer, and an orthographic projection of the planarization layer on the base substrate covers the pixel circuit;
the pixel circuit is electrically connected to anodes of the light-emitting elements through vias penetrating the planarization layer, and a thin film transistor of the pixel circuit is an oxide thin film transistor;
light transmittance of the planarization layer relative to light having wavelengths from 300 nm to 460 nm does not excess a predetermined percentage, and the predetermined percentage is in a range from 5% to 10%; and
a material of the planarization layer is a green filter material comprises a negative photoresist, or a red filter material comprises a negative photoresist.

7. A display device, comprising a display panel of claim 1, wherein the display device further comprises a touch functional layer on a side of the color film functional layer away from the display panel.

8. The display device of claim 7, wherein
the touch functional layer comprises a bridge electrode layer, a touch electrode layer, and an insulating spacer layer between the bridge electrode layer and the touch electrode layer,
the bridge electrode layer comprises a plurality of first bridge electrodes,
the touch electrode layer comprises a plurality of touch electrodes and a plurality of second bridge electrodes,
the plurality of touch electrodes are arranged in rows and columns,
the first bridge electrodes are configured to connect the touch electrodes in a row direction, and the second bridge electrodes are configured to connect the touch electrodes in a column direction, and
the bridge electrode layer is on a surface of the color film functional layer away from the display panel.

9. The display device of claim 8, wherein the plurality of first bridge electrodes, the plurality of second bridge electrodes and the plurality of touch electrodes of the touch functional layer comprises a metal material,
the plurality of touch electrode are formed into a grid shape with a plurality of grid openings, and the plurality of color filter blocks correspond to the plurality of grid openings.

10. The display device of claim 9, wherein the touch functional layer further comprises a black matrix at least covering the touch electrode layer, light outlets are formed in the black matrix, and the light outlets of the black matrix correspond to the plurality of grid openings.

11. The display device of claim 10, wherein an area of a surface of the black matrix away from the color film functional layer is smaller than an area of a surface of the black matrix proximal to the color film functional layer, so as to form side surfaces of the light outlets as an inclined surface.

12. The display device of claim 9, wherein
the touch functional layer further comprises a transparent protective layer, and
an orthographic projection of the transparent protective layer on the base substrate covers a layer where the black matrix are located.

13. The display device of claim 12, wherein the transparent protective layer comprises a transparent substrate and a plurality of scattering particles dispersed in the transparent substrate.

14. The display device of claim 12, wherein
the transparent protective layer comprises scattering blocks and a transparent protective layer, with the scattering blocks being located in the plurality of light outlets, and the transparent protective layer being on a side of the scattering blocks away from the display panel, and
each of the scattering blocks comprises a transparent substrate and a plurality of scattering particles dispersed in the transparent substrate.

15. The display device of claim 13, wherein the plurality of scattering particles have the same colors as the colors of the plurality of color filter blocks.

16. The display device of claim 13, wherein a thickness of the transparent protective layer is 1 to 3 times a thickness of the black matrix.

17. A method for manufacturing a display device, comprising:
providing a display substrate;
providing a color film functional layer, comprising:
forming a planarized transparent base layer, with a plurality of accommodating grooves formed on a surface of the planarized transparent base layer away from a display substrate; and
forming a color film layer comprising a plurality of color filter blocks in various colors, with the plurality of color filter blocks located in the plurality of accommodating grooves, orthographic projections of the plurality of accommodating grooves on the display substrate overlapping with orthographic projections of the plurality of color filter blocks on the display substrate, and the orthographic projections of the plurality of color filter blocks on the display substrate covering pixel openings of the display substrate; and
providing a touch functional layer.

18. The method of claim 17, wherein providing the touch functional layer comprises:
forming a bridge electrode layer comprising a plurality of first bridge electrodes;
forming an insulating spacer layer;
forming a touch electrode layer comprising a plurality of touch electrodes and a plurality of second bridging electrodes, with the plurality of touch electrodes arranged in rows and columns, the plurality of first bridge electrodes configured to connect the touch electrodes in a row direction, the plurality of second bridge electrodes configured to connect the touch electrodes in a column direction, the plurality of touch electrodes comprises a metal material, the plurality of touch electrodes formed into a grid shape with a plurality of grid openings, and the plurality of color filter blocks corresponding to the plurality of grid openings;
forming a black matrix, with light outlets formed in black matrix covering the plurality of touch electrodes, and the light outlets of the black matrix corresponding to the plurality of grid openings; and
forming a transparent protective layer.

19. The method of claim 18, wherein
forming the transparent protective layer comprises:
forming scattering blocks in the light outlets of the black matrix, with each of the scattering blocks comprising a transparent substrate and scattering particles dispersed in the transparent substrate, and colors of the scattering particles being the same as colors of the plurality of color filter blocks; and
forming an outer transparent protective layer; or
forming the transparent protective layer comprises:
the transparent protective layer comprises a transparent substrate and scattering particles dispersed in the transparent substrate, and colors of the scattering particles are the same as colors of the plurality of color filter blocks.
